(19) United States
(12) Patent Application Publication
(10) Pub. No.: US 2010/0067211 A1
(43) Pub. Date: Mar. 18, 2010

(54) DISPLAY SUBSTRATE AND DISPLAY APPARATUS HAVING THE SAME

(76) Inventors: Mi-Jung Han, Yongin-si (KR); Tae-Hyung Hwang, Seoul (KR); Sung-Jin Hong, Seoul (KR)

Correspondence Address: F. CHAU & ASSOCIATES, LLC, 130 WOODBURY ROAD, WOODBURY, NY, 11797, US

(21) Appl. No.: 12/558,075

(22) Filed: Sep. 11, 2009

(30) Foreign Application Priority Data
Sep. 12, 2008 (KR) 10-2008-90234

(51) Int. Cl. H05K 9/00

(52) U.S. Cl. 361/818

(57) ABSTRACT

A display substrate includes a base substrate having a plurality of pixel areas, a switching device arranged in each pixel area to switch a pixel voltage, a pixel electrode arranged in each pixel area and electrically connected to the switching device to receive the pixel voltage, and a shielding member positioned between two adjacent pixel areas.

### CROSS-REFERENCE TO RELATED APPLICATION

This application claims priority to Korean Patent Application No. 2008-90234 filed on Sep. 12, 2008, the contents of which are herein incorporated by reference in its entirety.

### BACKGROUND OF THE INVENTION

1. Technical Field

The present disclosure relates to a display substrate and a display apparatus having the same, and more particularly, to a display substrate having a shielding member and a display apparatus having the display substrate.

2. Discussion of the Related Art

In a display apparatus, electrical signals processed by an information-processing device are converted into image signals to display images. The display apparatus includes, for example, an electrophoretic display apparatus. The electrophoretic display apparatus is thinner and lighter as compared to a cathode ray tube display apparatus or a liquid crystal display.

The electrophoretic display apparatus includes lower and upper substrates each of which having an electrode arranged thereon, and pigment particles interposed between the lower and upper substrates. The pigment particles move to the lower or upper substrate according to an electric field applied between the lower and upper substrates. The electrophoretic display apparatus displays images using an electrophoretic phenomenon where the pigment particles move according to the electric field. The electrophoretic display apparatus is a reflective type display apparatus where no separate light source is required. The pigment particles are formed in a thin layer.

The electrophoretic display apparatus includes a plurality of pixel parts each of which receives a pixel voltage. The electric field is formed between the lower and upper substrates in each pixel part. However, a fringe field is generated between two adjacent pixel parts, thereby causing the electric field interference between the two adjacent pixel parts. As a result, the reflectance of the electrophoretic display apparatus is lowered and color reproducibility is lowered.

### SUMMARY OF THE INVENTION

According to an exemplary embodiment of the present invention, a display substrate comprises a base substrate having a plurality of pixel areas, a switching device arranged in each pixel area to switch a pixel voltage, a pixel electrode arranged in each pixel area and electrically connected to the switching device to receive the pixel voltage, and a shielding member positioned between two adjacent pixel areas.

The shielding member may comprise a conductive material and can be thicker than the pixel electrode.

The display substrate may further comprise a plurality of data lines arranged on the base substrate and electrically connected to the switching device, and a plurality of gate lines arranged on the base substrate, insulated from the data lines and crossing the data lines, and electrically connected to the switching device, wherein the shielding member is arranged above the data lines.

The shielding member may have a thickness of about 120 percent of a thickness of the pixel electrode.

The shielding member may extend along a corresponding data line.

The shielding member may comprise metal or a conductive polymer.

The conductive polymer may comprise at least one of polyvinylidene difluoride (PVDF), polyanyline, polyathetylene, polypyrol, or carbon nano tube.

According to an exemplary embodiment of the present invention, a display apparatus comprises a first display substrate, a second display substrate facing the first display substrate, the second display substrate coupling with the first display substrate, and a gray scale adjustment layer interposed between the first display substrate and the second display substrate to adjust a gray scale in response to a pixel voltage, wherein the first display substrate comprises a base substrate having a plurality of pixel areas, a switching device arranged in each pixel area to switch the pixel voltage, a pixel electrode arranged in each pixel area and electrically connected to the switching device to receive the pixel voltage, and a shielding member positioned between two adjacent pixel areas.

The shielding member may comprise a conductive material and is thicker than the pixel electrode.

The gray scale adjustment layer may comprise a plurality of electrophoretic particles.

The first display substrate may further comprise a plurality of data lines arranged on the base substrate and electrically connected to the switching device, and a plurality of gate lines arranged on the base substrate, insulated from the data lines and crossing the data lines, and electrically connected to the switching device, wherein the shielding member is arranged above the data lines.

The shielding member may have a thickness of about 120 percent of a thickness of the pixel electrode.

The shielding member may extend along a corresponding data line.

The first display substrate may further comprise an organic insulating layer formed on the first base substrate, and the shielding member and the pixel electrode are formed on the organic insulating layer.

The pixel electrode can be spaced apart from a corresponding data line by about 4 micrometers.

The second display substrate may comprise a second base substrate facing the first base substrate, and a common electrode interposed between the second base substrate and the gray scale adjustment layer, the common electrode spaced apart from the shielding member to receive a common voltage.

The shielding member may comprise metal or a conductive polymer.

The conductive polymer may comprise at least one of polyvinylidene difluoride (PVDF), polyanyline, polyathetylene, polypyrol, or carbon nano tube.

According to an exemplary embodiment of the present invention, a display substrate comprises a base substrate having a plurality of pixel areas, a switching device arranged in each pixel area to switch a pixel voltage, a plurality of data lines arranged on the base substrate and electrically connected to the switching device, a plurality of gate lines arranged on the base substrate, insulated from the data lines and crossing the data lines, and electrically connected to the switching device, a pixel electrode arranged in each pixel area and electrically connected to the switching device to receive the pixel voltage, and a shielding member arranged above the data lines.

The shielding member may include a conductive material.

The shielding member can be formed on a same layer as the pixel electrode.

The shielding member can be thicker than the pixel electrode.

### BRIEF DESCRIPTION OF THE DRAWINGS

Exemplary embodiments of the present invention can be understood in more detail from the following description taken in conjunction with the accompanying drawings in which:

FIG. 1 is a sectional view of an electrophoretic display apparatus according to an exemplary embodiment of the present invention;

FIG. 2 is a plan view showing a first substrate of FIG. 1 according to an exemplary embodiment of the present invention;

FIG. 3 is a partially enlarged sectional view showing the portion A of FIG. 1 according to an exemplary embodiment of the present invention;

FIG. 4 is a partially enlarged plan view showing the portion B of FIG. 2 according to an exemplary embodiment of the present invention;

FIG. 5 is a view showing electric fields in pixel areas of FIG. 1 according to an exemplary embodiment of the present invention; and

FIG. 6 is a sectional view showing an electrophoretic display apparatus according to an exemplary embodiment of the present invention.

### DESCRIPTION OF EXEMPLARY EMBODIMENTS

Exemplary embodiments of the present invention will be described below in more detail with reference to the accompanying drawings. The present invention may, however, be embodied in many different forms and should not be construed as limited to the exemplary embodiments set forth herein.

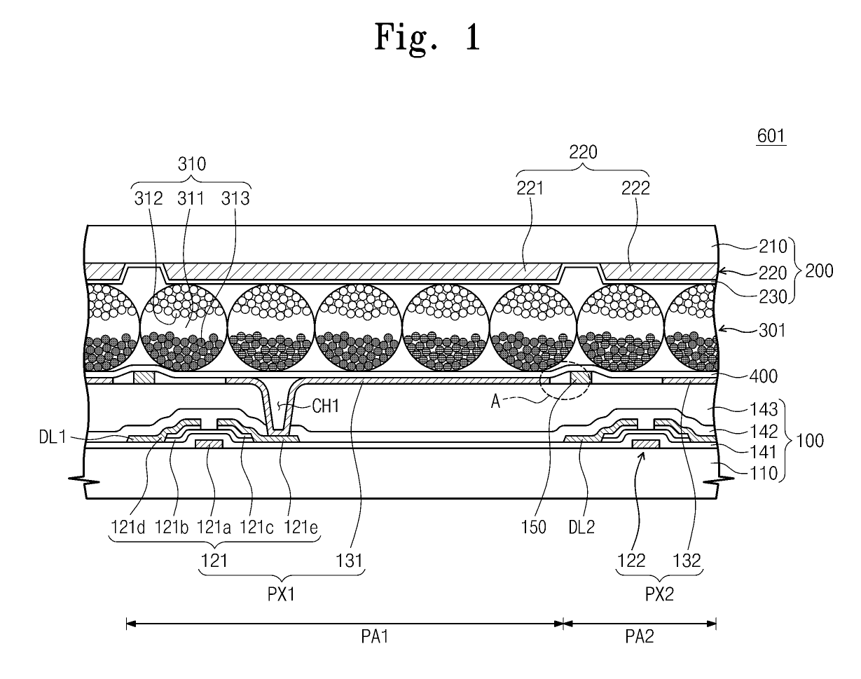

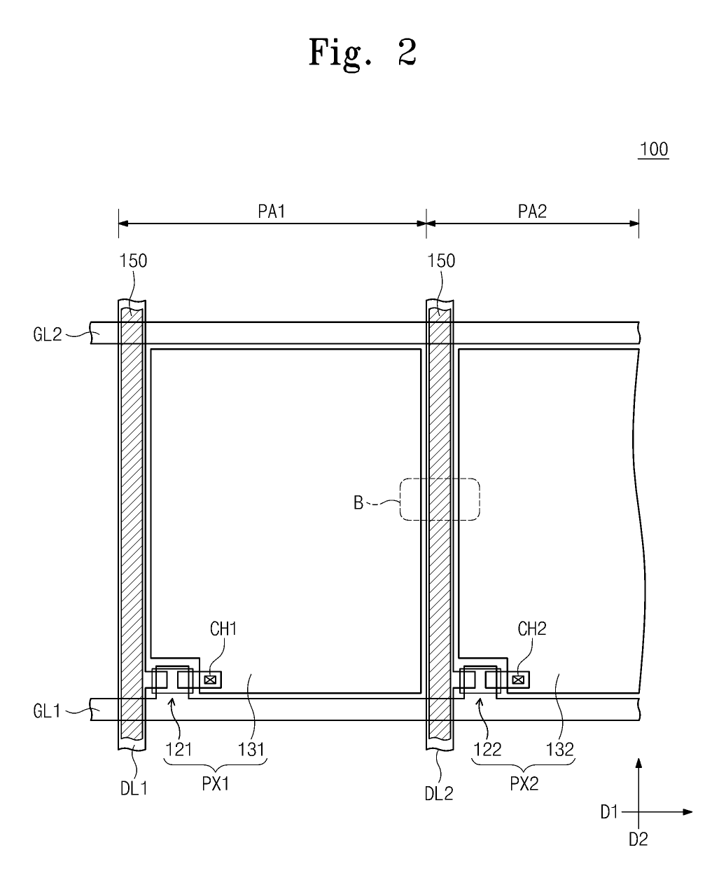

It will be understood that when an element or layer is referred to as being “on”, “connected to” or “coupled to” another element or layer, it can be directly on, connected or coupled to the other element or layer or intervening elements or layers may be present. Referring to FIGS. 1 and 2, an electrophoretic display apparatus 601 includes a first display substrate 100, a second display substrate 200 facing the first display substrate 100, and an electrophoretic layer 301 disposed between the first and second display substrates 100 and 200.

The first display substrate 100 includes a first base substrate 110, a plurality of gate lines GL1 and GL2, a plurality of data lines DL1 and DL2, a plurality of pixel parts PX1 and PX2, and a shielding member 150.

In an exemplary embodiment, the first base substrate 110 includes a plurality of pixel areas PA1 and PA2 defined therein.

The gate lines GL1 and GL2 transmitting gate signals extend in a first direction D1 on the first base substrate 110. The gate lines GL1 and GL2 are spaced apart from each other along a second direction D2. The second direction D2 is substantially perpendicular to the first direction D1. The data lines DL1 and DL2 are arranged on the first base substrate 110 on which the gate lines GL1 and GL2 are arranged. The data lines DL1 and DL2 are insulated from the gate lines GL1 and GL2 and cross the gate lines GL1 and CL2. The data lines DL1 and DL2 extend in the second direction D2 and are spaced apart from each other along the first direction D1. In an exemplary embodiment, the gate lines GL1 and GL2, with the data lines DL1 and DL2, define the first and second pixel areas PA1 and PA2.

Each of the first and second pixel areas PA1 and PA2 includes one pixel part. A pixel part PX1 formed in the first pixel area PA1 is described as a first pixel part PX1 and a pixel part PX2 formed in the second pixel area PA2 is described as a second pixel part PX2. When viewed in a plan view, the first and second pixel parts PX1 and PX2 are located at both sides of the second data line DL2.

In an exemplary embodiment, the first and second pixel parts PX1 and PX2 have substantially the same structure and function.

The first pixel part PX1 includes a thin film transistor 121 that switches a pixel voltage and a pixel electrode 131 that is electrically connected to the thin film transistor 121.

In an exemplary embodiment, the thin film transistor 121 includes a gate electrode 121a that branches from the first gate line GL1, an active layer 121b and an ohmic contact layer 121c that are sequentially formed on the gate electrode 121a, a source electrode 121d that branches from the first data line DL1 and is formed on the ohmic contact layer 121c, and a drain electrode 121e that is formed on the ohmic contact layer 121c. The pixel electrode 131 is electrically connected to the drain electrode 121e to receive the pixel voltage. The pixel electrode 131 includes a transparent conductive material such as indium zinc oxide (IZO) or indium tin oxide (ITO).

The second pixel part PX2 is located adjacent to the first pixel part PX1 in the first direction D1. The thin film transistor 122 of the second pixel part PX2 includes a gate electrode branching from the first gate line GL1 and a source electrode branching from the second data line DL2.

In an exemplary embodiment, the first display substrate 100 may further include a gate insulating layer 141, a protective layer 142, and an organic insulating layer 143. The gate insulating layer 141 is formed on the first base substrate 110 to cover the gate lines GL1 and GL2 and the gate electrodes. A protective layer 142 and an organic insulating layer 143 are sequentially formed on the gate insulating layer 141 to cover the data lines DL1 and DL2 and the thin film transistors 121 and 122. The protective layer 142 and the organic insulating layer 143 are provided with contact holes CH1 and CH2 formed therethrough to respectively expose the drain electrodes of the thin film transistors 121 and 122. The pixel electrodes 131 and 132 of the first and second pixel parts PX1 and PX2 are formed on the organic insulating layer 143 and electrically connected to the drain electrodes respectively through the contact holes CH1 and CH2.

The shielding member 150 is formed on the organic insulating layer 143 to overlap the data lines DL1 and DL2. The shielding member 150 prevents the electric field interference between the first and second pixel parts PX1 and PX2.

In an exemplary embodiment, the shielding member 150 is positioned between the first and second pixel parts PX1 and PX2 adjacent to each other in the first direction D1 in a plan view. The shielding member 150 extends in the second direction D2 along the second data line DL2. The shielding member 150 positioned between the first and second pixel parts PX1 and PX2 overlaps the second data line DL2.

Since the shielding member 150 is formed above the second data line DL2 positioned between first and second pixel parts PX1 and PX2, the shielding member 150 may prevent the electric field interference between the second data line DL2 and the pixel electrodes 131 and 132 that are adjacent to each other. Accordingly, an image distortion above the second data line DL2 can be prevented.

In an exemplary embodiment, the shielding member 150 is formed on the same layer as the pixel electrodes 131 and 132, and is formed on the organic insulating layer 143.

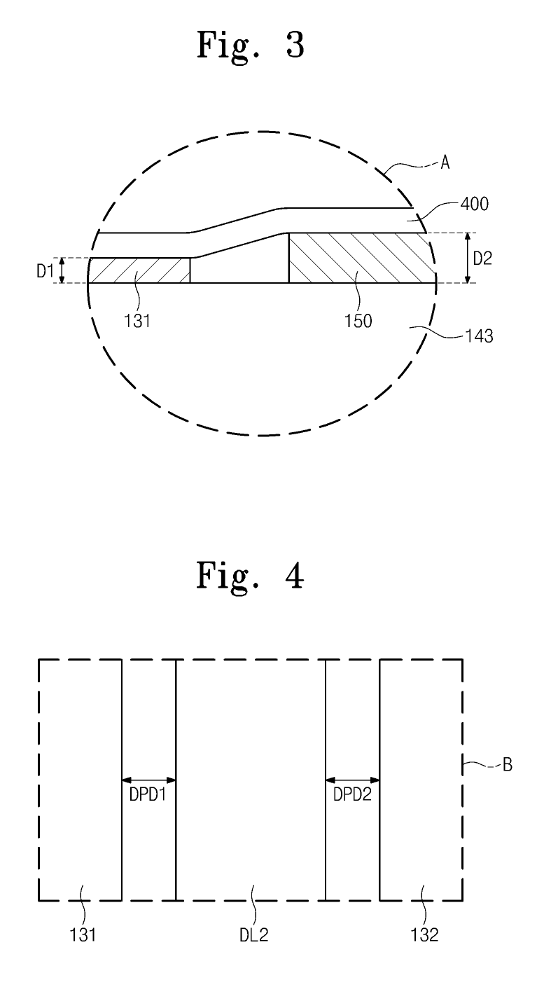

Referring to FIGS. 1 and 3, the shielding member 150 has a thickness D2 of about 120 percent of a thickness D1 of the pixel electrodes 131 and 132 according to an exemplary embodiment of the present invention. In an exemplary embodiment, the shielding member 150 includes a conductive material such as metal, or a conductive polymer. As the conductive polymer, polyvinylidene difluoride (PVDF), polyanyline, polyathetylene, polypyrol, and carbon nano tube may be used.

Since the shielding member 150 has the thickness D2 thicker than the thickness D1 of the pixel electrodes 131 and 132 and includes the conductive material, the shielding member 150 may prevent the electric field interference between the first and second pixel parts PX1 and PX2. The first and second pixel parts PX1 and PX2 are adjacent to each other and the second data line DL2 is interposed therebetween. Thus, the first display substrate 100 may prevent the electric field interference between adjacent pixel parts, thereby improving the image display quality.

Referring to FIGS. 2 and 4, when viewed in a plan view, the pixel electrode 131 of the first pixel part PX1 is spaced apart from the second data line DL2 by a first interval DPD1, and the pixel electrode 132 of the second pixel part PX2 is spaced apart from the second data line DL2 by a second interval DPD2. In an exemplary embodiment, the first interval DPD1 is about 4 micrometers and is substantially identical with the second interval DPD2.

That is, although the first interval DPD1 between the pixel electrode 131 and the second data line DL2 and the second interval DPD2 between the pixel electrode 132 and the second data line DL2 are reduced to about 4 micrometer, the electric field interference between the first and second pixel parts PX1 and PX2 may be prevented since the shielding member 150 is formed corresponding to the second data line DL2 between the first and second pixel parts PX1 and PX2.

Referring to FIG. 1, the second display substrate 200 is disposed above the first display substrate 100.

The second display substrate 200 includes a second base substrate 210, a color filter 220, and a common electrode 230.

The second base substrate 210 faces the first base substrate 110 and includes a flexible material such as polyethyleneterephthalate (PET), fiber reinforced plastic, or polyethylene naphthalate (PEN).

The color filter 220 is formed on a lower surface of the second base substrate 210 and includes a plurality of color pixels 221 and 222. The color pixels 221 and 222 correspond to the pixel areas PA1 and PA2 in one-to-one correspondence, and each of the color pixels 221, 222 has a predetermined color. The color pixels 221 and 222 represent respective colors using light reflected by the electrophoretic layer 301, so that images are displayed.

The common electrode 230 is formed on the color filter 220. The common electrode 230 is positioned between the color filter 220 and the electrophoretic layer 301. The common electrode 230 receives a common voltage. The common electrode 230 includes a transparent conductive material such that external light incident to the second base substrate 210 from the exterior is provided to the electrophoretic layer 301 through the common electrode 230.

A gray scale adjustment layer such as the electrophoretic layer 301 is interposed between the first and second display substrates 100 and 200. The electrophoretic layer 301 includes a plurality of microcapsules 310. Each of the microcapsules 310 has a spherical shape in an exemplary embodiment. Each microcapsule 310 has an approximate diameter of, for example, a human hair. Each microcapsule 310 may include a fluid medium 311 having a transparent insulative liquid, and first and second particles 312 and 313 dispersed into the fluid medium 311. The first and second particles 312 and 313 are electrified to have different polarities from each other. The first particles 312 may have a color different from that of the second particles 313.

As an example, the first particles 312 are electrified to have a positive polarity and include titanium dioxide (TiO2), so that the first particles 312 are white. The second particles 313 are electrified to have a negative polarity and include carbon power such as carbon black, so that the second particles 313 are black. The first and second particles 312 and 313 are arranged at different positions according to the electric field generated between the first and second display substrates 100 and 200. The electric field generated between the first and second display substrates 100 and 200 depends upon the pixel voltage applied to each pixel electrode 121 and 122. Accordingly, the electric field may be different according to the pixel voltage in each pixel area PA1 and PA2, so that positions of the first and second particles 312 and 313 may be different in each pixel area PA1 and PA2.

For instance, when an electric field having a positive potential is generated between the first and second display substrates 100 and 200 corresponding to the first pixel area PA1, the second particles 313 in the first pixel area PA1 move to the first display substrate 100 and first particles 312 in the first pixel area PA1 move to the second display substrate 200.

When an electric field having a negative potential is generated between the first and second display substrates 100 and 200 corresponding to the first pixel area PA1, the first particles 312 in the first pixel area PA1 move to the first display substrate 100 and the second particles 313 in the first pixel area PA1 move to the second display substrate 200.

A number of the first particles 312 or a number of the second particles 313 of the electrophoretic layer 301, moving to the first and second display substrate 100 and 200, is determined depending on the pixel voltage applied to the pixel areas PA1 and PA2. A gray scale level in each pixel area PA1 and PA2 is determined by the amount of moving first and second particles 312 and 313. The color pixels 221 and 222 represent respective colors using the light reflected by the first and second particles 312 and 313 in a corresponding pixel area.

The electrophoretic display apparatus 601 may further include an adhesive member 400 to attach the electrophoretic layer 301 to the first display substrate 100. The adhesive member 400 is disposed between the electrophoretic layer 301 and the first display substrate 100 to attach the first display substrate 100 to the electrophoretic layer 301.

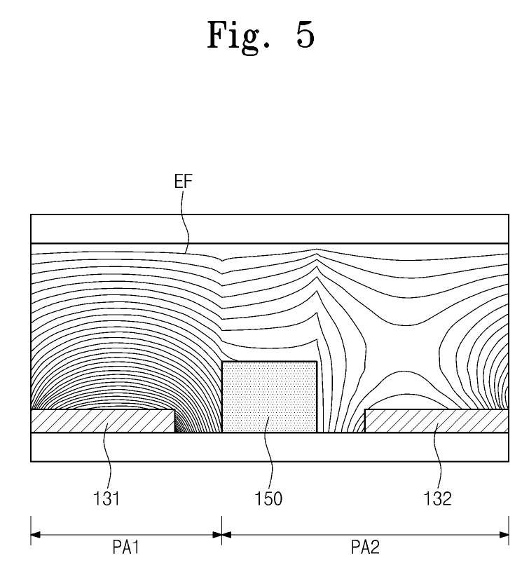

FIG. 5 is a view showing electric fields in pixel areas PA1 and PA2 of FIG. 1 according to an exemplary embodiment of the present invention.

In FIG. 5, an electric field EF in the first and second pixel areas PA1 and PA2 is shown after the pixel voltage of about 15V is applied to the pixel electrode 131 of the first pixel area PA1 and the pixel voltage of about 0V is applied to the pixel electrode 132 of the second pixel area PA2.

Referring to FIG. 5, the shielding member 150 positioned between the first and second pixel areas PA1 and PA2 blocks the electric field EF of the first pixel area PA1 from reaching the second pixel area PA2.

The shielding member 150 prevents the electric field interference between a pixel area to which a voltage is applied and a pixel area to which a voltage is not applied. Thus, the electrophoretic display apparatus 601 may prevent the color-mixing phenomenon between adjacent pixel areas, thereby improving the image display quality.

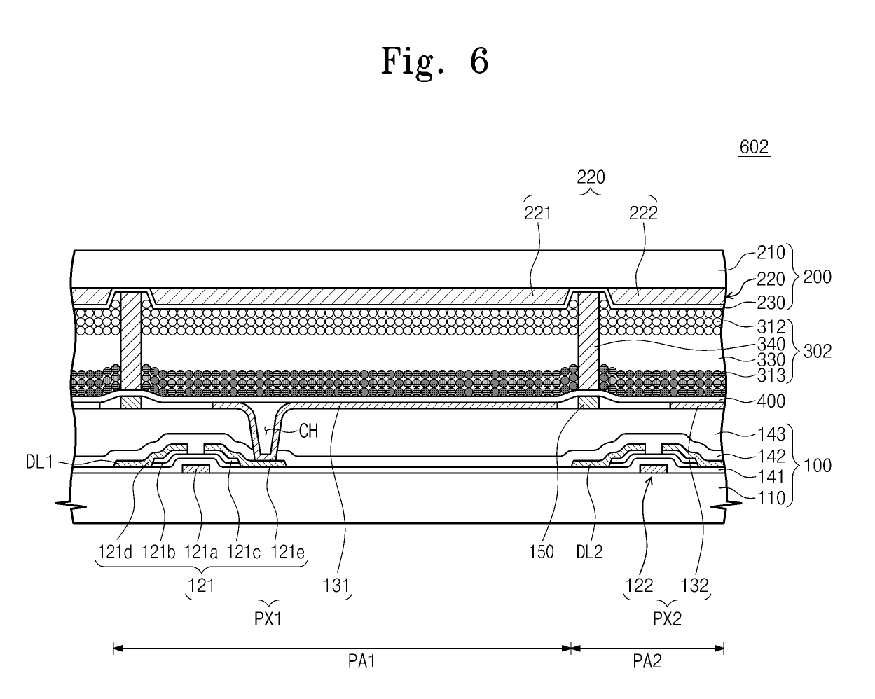

FIG. 6 is a sectional view showing an electrophoretic display apparatus according to an exemplary embodiment of the present invention. In FIG. 6, an electrophoretic display apparatus 602 has substantially the same function and structure as those of the electrophoretic display apparatus 601 shown in connection with FIG. 1 except for an electrophoretic layer 302.

Referring to FIG. 6, an electrophoretic layer 302 is interposed between the first display substrate 100 and the second display substrate 200.

The first display substrate 100 may include a first base substrate 110 on which a plurality of pixel areas PA1 and PA2 is defined, and a plurality of pixel parts PX1 and PX2 formed on the first base substrate 110 to receive pixel voltages.

The second display substrate 200 may include a second base substrate 210 disposed above the first base substrate 110, a color filter 220 formed on the second base substrate 210, and a common electrode 230 interposed between the color filter 220 and the electrophoretic layer 302. The electrophoretic layer 302 includes a fluid layer 330 having a transparent insulative liquid, and first and second particles 312 and 313 scattered in the fluid layer 330, and a barrier wall 340.

The first particles 312 have a color and a polarity different from those of the second particles 313. The first and second particles 312 and 312 in FIG. 6 have substantially the same function and structure as those of the first and second particles 312 and 313 in FIG. 1.

The first and second particles 312 and 313 are arranged at different positions according to the electric field generated between the first and second display substrates 100 and 200. The electric field generated between the first and second display substrates 100 and 200 depends upon the pixel voltage applied to the pixel electrodes 131 and 132. Accordingly, the electric field may be different according to the pixel voltage in each pixel area PA1 and PA2, so that positions of the first and second particles 312 and 313 may be different in each pixel area PA1 and PA2.

A number of the first particles 312 or a number of the second particles 313 of the electrophoretic layer 302, moving to the first and second display substrate 100 and 200, is determined depending on the pixel voltage applied to the pixel areas PA1 and PA2. A gray scale level in each pixel area PA1 and PA2 is determined by the amount of the first and second particles 312 and 313 that are moved.

The barrier wall 340 separates the first and second display substrates 100 and 200 from each other to provide a space in which the fluid layer 340, the first particles 312, and the second particles 313 are accommodated. The barrier wall 340 surrounds each pixel area PA1 and PA2 and prevents movement of the fluid layer 340, the first particles 312, and the second particles 313 between the pixel areas PA1 and PA2.

The electrophoretic display apparatus 602 may further includes an adhesive member 400 to attach the electrophoretic layer 302 to the first display substrate 100.

According to an exemplary embodiment of the present invention, the shielding member is formed between two adjacent pixel areas to prevent the electric field interference between the two adjacent pixel areas.

In an exemplary embodiment, the electrophoretic display apparatus may prevent the color-mixing phenomenon between adjacent pixel areas, thereby improving the image display quality.

Although the exemplary embodiments of the present invention have been described, it is understood that the present invention should not be limited to these exemplary embodiments but various changes and modifications can be made by one ordinary skilled in the art within the spirit and scope of the present invention. All such changes and modifications are intended to be included within the scope of the invention as defined by the appended claims.

What is claimed is:

1. A display substrate comprising:
a base substrate comprising a plurality of pixel areas;
a switching device arranged in each pixel area to switch a pixel voltage;
a pixel electrode arranged in each pixel area and electrically connected to the switching device to receive the pixel voltage; and
a shielding member positioned between two adjacent pixel areas, the shielding member comprises a conductive material and is thicker than the pixel electrode.

2. The display substrate of claim 1, further comprising:
a plurality of data lines arranged on the base substrate and electrically connected to the switching device; and
a plurality of gate lines arranged on the base substrate, insulated from the data lines and crossing the data lines, and electrically connected to the switching device,
wherein the shielding member is arranged above the data lines.

3. The display substrate of claim 2, wherein the shielding member comprises a thickness of about 120 percent of a thickness of the pixel electrode.

4. The display substrate of claim 3, wherein the shielding member extends along a corresponding data line.

5. The display substrate of claim 3, wherein the shielding member comprises metal or a conductive polymer.

6. The display substrate of claim 5, wherein the conductive polymer comprises at least one of polyvinylidene difluoride (PVDF), polyanyline, polyathetylene, polypyrol, or carbon nano tube.

7. A display apparatus comprising:
a first display substrate;
a second display substrate facing the first display substrate, the second display substrate coupling with the first display substrate; and
a gray scale adjustment layer interposed between the first display substrate and the second display substrate to adjust a gray scale in response to a pixel voltage,
wherein the first display substrate comprises:
a base substrate comprising a plurality of pixel areas;
a switching device arranged in each pixel area to switch the pixel voltage;
a pixel electrode arranged in each pixel area and electrically connected to the switching device to receive the pixel voltage; and
a shielding member positioned between two adjacent pixel areas, the shielding member comprises a conductive material and is thicker than the pixel electrode.

8. The display apparatus of claim 7, wherein the gray scale adjustment layer comprises a plurality of electrophoretic particles.

9. The display apparatus of claim 7, wherein the first display substrate further comprises:
a plurality of data lines arranged on the base substrate and electrically connected to the switching device; and
a plurality of gate lines arranged on the base substrate, insulated from the data lines and crossing the data lines, and electrically connected to the switching device,
wherein the shielding member is arranged above the data lines.

10. The display apparatus of claim 9, wherein the shielding member comprises a thickness of about 120 percent of a thickness of the pixel electrode.

11. The display apparatus of claim 10, wherein the shielding member extends along a corresponding data line.

12. The display apparatus of claim 10, wherein the first display substrate further comprises an organic insulating layer formed on the first base substrate, and the shielding member and the pixel electrode are formed on the organic insulating layer.

13. The display apparatus of claim 10, wherein the pixel electrode is spaced apart from a corresponding data line by about 4 micrometers.

14. The display apparatus of claim 10, wherein the second display substrate comprises:
a second base substrate facing the first base substrate; and
a common electrode interposed between the second base substrate and the gray scale adjustment layer, the common electrode spaced apart from the shielding member to receive a common voltage.

15. The display apparatus of claim 10, wherein the shielding member comprises metal or a conductive polymer.

16. The display apparatus of claim 15, wherein the conductive polymer comprises at least one of polyvinylidene difluoride (PVDF), polyanyline, polyathetylene, polypyrol, or carbon nano tube.

17. A display substrate comprising:
a base substrate comprising a plurality of pixel areas;
a switching device arranged in each pixel area to switch a pixel voltage;
a plurality of data lines arranged on the base substrate and electrically connected to the switching device;
a plurality of gate lines arranged on the base substrate, insulated from the data lines and crossing the data lines, and electrically connected to the switching device;
a pixel electrode arranged in each pixel area and electrically connected to the switching device to receive the pixel voltage; and
a shielding member arranged above the data lines, the shielding member comprises a conductive material.

18. The display substrate of claim 17, wherein the shielding member is formed on a same layer as the pixel electrode.

19. The display substrate of claim 18, wherein the shielding member is thicker than the pixel electrode.
